(19) United States
(12) Patent Application Publication
(10) Pub. No.: US 2011/0039034 A1
(43) Pub. Date: Feb. 17, 2011

(54) PULSED DEPOSITION AND RECRYSTALLIZATION AND TANDEM SOLAR CELL DESIGN UTILIZING CRYSTALLIZED/AMORPHOUS MATERIAL

(76) Inventors: Helen Maynard, North Reading, MA (US); George D. Papasouliotis, North Andover, MA (US); Vikram Singh, North Andover, MA (US); Christopher Hatem, Cambridge, MA (US); Ludovic Godet, North Reading, MA (US)

Correspondence Address: Nields, Lemack & Frame, LLC, 176 E. MAIN STREET, SUITE 5, WESTBOROUGH, MA, 01581, US

(21) Appl. No.: 12/538,913

(22) Filed: Aug. 11, 2009

(51) Int. Cl. C23C 14/14; C23C 14/00

(52) U.S. Cl. 427/527; 427/523

(57) ABSTRACT

A method of depositing and crystallizing materials on a substrate is disclosed. In a particular embodiment, the method may include creating a plasma having deposition-related species and energy-carrying species. During a first time period, no bias voltage is applied to the substrate, and species are deposited on the substrate via plasma deposition. During a second time period, a voltage is applied to the substrate, which attracts ions to and into the deposited species, thereby causing the deposited layer to crystallize. This process can be repeated until an adequate thickness is achieved. In another embodiment, the bias voltage or bias pulse duration can be varied to change the amount of crystallization that occurs. In another embodiment, a dopant may be used to dope the deposited layers.

### BACKGROUND OF THE INVENTION

The widespread adoption of emerging technologies such as flat panel displays (FPD) and solar cells depends on the ability to manufacture electrical devices on low cost substrates. In manufacturing FPD, pixels of a typical low cost flat panel display (FPD), are switched by thin film transistors (TFT) which may be typically manufactured on thin (−50 nm thick) films of amorphous silicon deposited on inert, glass substrates. However, improved FPDs demand better performing pixel TFTs, and it may be advantageous to manufacture high performance control electronics directly onto the panel. One advantage may be to eliminate the need for costly and potentially unreliable connections between the panel and external control circuitry.

Current FPDs contain a layer of silicon that is deposited onto the glass panel of the display via a low temperature deposition process such as sputtering, evaporation, plasma enhanced chemical vapor deposition (PECVD), or low pressure chemical vapor deposition (LPCVD) process. Such low temperature processes are desirable, as the panel used to manufacture FPD tends to be amorphous and has glass transition temperature of approximately 600° C. If manufactured above 600° C., the panel may have a non-uniform or uneven structure or surface. Higher temperature tolerant glass panels such as quartz or sapphire panel exist; however, the high cost of such glasses discourages their use. Further cost reduction would be possible if cheaper, lower temperature tolerant glass or plastic panels could be used.

The low temperature deposition process, however, does not yield optimal silicon film. As known in the art, solid silicon has three common phases: amorphous, poly-crystalline, and mono-crystalline phases. If silicon is deposited at low temperature, the deposited silicon film tends to be in an amorphous phase. The channels of thin film transistors based on amorphous silicon film may have lower mobility compared to those on either poly-crystalline or mono-crystalline silicon films.

To obtain a polycrystalline or mono-crystalline silicon layer, the panel may undergo further processes to convert the amorphous silicon film to either polycrystalline or mono-crystalline film. To obtain a panel with poly-crystalline silicon film, the panel may undergo an excimer laser annealing (ELA) process. An example of the ELA process may be found in more detail in U.S. Pat. No. 5,766,989. To obtain a panel with larger crystals, the panel may undergo a process known as Sequential Lateral Solidification (“SLS”) process. An example of SLS process may be found in U.S. Pat. No. 6,322,625. Although ELA and SLS processes may result in a panel with mono-crystalline or poly-crystalline silicon thin film, each process is not without disadvantages. For example, excimer lasers used in both processes may be expensive to operate, resulting in an expensive TFT. In addition, the duty cycle may not be optimum for the best conversion of amorphous silicon into crystalline silicon. Further, the excimer laser may have pulse-to-pulse variations and spatial non-uniformity in the delivered power that may affect the uniformity of the processes. There may also be intra-pulse non-uniformity that may be caused by for example, self-interference of the beam. Such inter-pulse and intra-pulse non-uniformity may result in silicon films with non-uniform crystals.

These issues also exist in the manufacturing of solar cells. The ability to produce low cost amorphous or crystalline silicon can decrease the cost of these panels, thereby increasing their attractiveness as an alternative energy source. As such, new methods and apparatus for particle processing for the cost effective and production worthy manufacture of high quality crystalline materials on low cost substrates are needed. In addition, the ability to selectively create silicon layers that are either amorphous or crystalline may aid in the production of solar cells.

### SUMMARY OF THE INVENTION

A method of depositing and crystallizing materials on a substrate is disclosed. In a particular embodiment, the method may include creating a plasma having deposition-related species and energy-carrying species. During a first time period, no bias voltage is applied to the substrate, and species are deposited on the substrate via plasma deposition. During a second time period, a voltage is applied to the substrate, which attracts ions to and into the deposited species, thereby causing the deposited layer to crystallize. This process can be repeated until an adequate thickness is achieved. In another embodiment, the bias voltage or bias pulse duration can be varied to change the amount of crystallization that occurs. In another embodiment, a dopant may be used to dope the deposited layers.

### BRIEF DESCRIPTION OF THE DRAWINGS

In order to facilitate a fuller understanding of the present disclosure, reference is now made to the accompanying drawings, in which like features are referenced with like numerals. These figures should not be construed as limiting the present disclosure, but are intended to be exemplary only.

FIG. 1 is a block diagram of various mechanisms through which amorphous material may transform into crystalline material;

FIG. 2 shows a plasma assisted doping system (PLAD) used with one embodiment;

FIG. 3 is a timing diagram showing the pulse pattern of the bias voltage;

FIG. 4 is a timing diagram showing the pulse pattern of the bias voltage with the status of the material provided;

FIG. 5 is a graph showing the thermal dependence of crystallization;

FIG. 6 is a timing diagram showing the pulse pattern of the bias voltage and a voltage waveform for the RF source power;

FIG. 7 shows a schematic diagram of a generic tandem cell;

FIG. 8 is a schematic diagram showing layers of amorphous and crystalline silicon; and

FIG. 9 is a schematic diagram showing a crystallization gradient in the deposited silicon.

### DETAILED DESCRIPTION OF THE INVENTION

As described above, high temperature annealing, such as by use of laser, can be expensive, thereby making it an unattractive alternative for the creation of FPDs and solar cells. Thus, alternative methods of creating crystalline silicon are desired.

In the present disclosure, several embodiments are described using a substrate. This substrate may be a wafer (for example, a silicon wafer) or a substrate comprising a plurality of films. In addition, the substrate may be an elemental substrate containing only one element (e.g. silicon wafer or metal foil); a compound substrate containing more than one element (e.g. SiGe, SiC, InTe, GaAs, InP, GaInAs, GaInP; CdTe; CdS; and combinations of (Cu, Ag and/or Au) with (Al, Ga, and/or In) and (S, Se and/or Te) such as CuInGaSe, CuInSe2, other group III-V semiconductors and other group II-VI compounds); and/or an alloy substrate. The material contained in the substrate may be metal, semiconductor, and/or insulator (e.g. glass, Polyethylene terephthalate (PET), sapphire, and quartz). Further, the substrate may be a thin film substrate containing multiple layers (e.g. SOI). If the substrate comprises multiple layers, at least one of the layers may be a semiconducting film or a metallic film, whereas another one of the films may be an insulator. The semiconducting or metallic film may be disposed on a single insulating film or, alternatively, interposed between a plurality of insulating films. Conversely, the insulating film may be disposed on a single semiconducting or metallic film or, alternatively, interposed between multiple semiconducting or metallic films or both.

The most rapid mechanism to crystallize thin amorphous silicon layers into crystalline layers is solid phase epitaxial re-growth (SPER). In SPER, amorphous silicon may transform to crystalline silicon by extending an underlying, pre-existing, extensive crystal layer. This scenario is commonly encountered during annealing of a surface layer of a crystalline silicon wafer after it has been amorphized by ion implantation. However, such a process typically begins with a crystalline substrate, which has become amorphous. The present disclosure relates to the process of depositing a crystalline film. Therefore, there may not be a pre-existing crystal layer that can be extended. Furthermore, when creating crystalline films, there may be no crystalline wafer, as the material may be deposited onto a substrate.

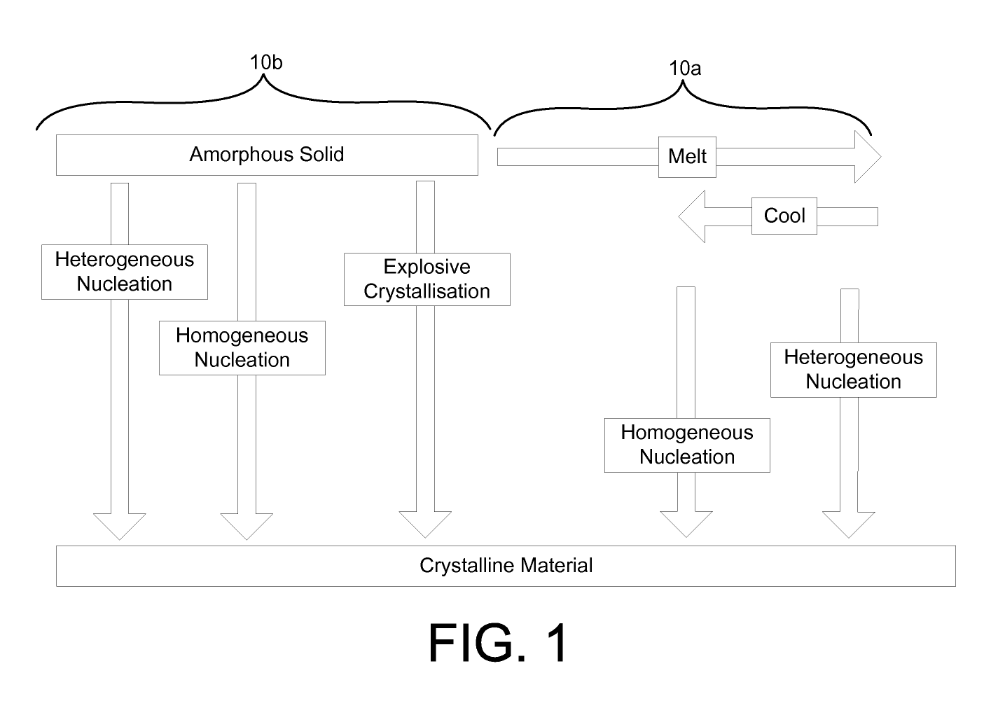

One method of creating a structure processing an amorphous substrate in which an extensive pre-existing lattice does not exist and which phase transformation occur via crystal nucleation prior to the growth of the crystals. Referring to FIG. 1, there is shown a block diagram of various mechanisms through which a material without extensive pre-existing lattice may transform from an amorphous phase into a crystalline phase. As known in the art, the crystalline phase may be categorized as a poly-crystalline phase or a mono-crystalline phase. The poly-crystalline phase may sometimes be further subdivided into different categories (such as multi-, micro-, nano-crystalline etc) depending on the crystal size. However, such a distinction may not be important in the context of this disclosure, and may not be necessary to describe FIG. 1. Accordingly, these phases may be referred herein collectively as a crystalline phase.

As illustrated in FIG. 1, the phase transformation from the amorphous phase to a crystalline phase may occur via various mechanisms. For example, the transformation may occur via melting and solidification mechanism 10a and solid phase crystallization (SPC) transformation mechanism 10b. In the melting and solidification mechanism 10a and SPC mechanism, the transformation may occur via nucleation of crystallites and growth of the crystallites. In the SPER mechanism, the transformation may occur by growth on the extensive pre-existing crystal lattice.

In the melting and solidification mechanism 10a, energy in the form of radiation, heat, or kinetic energy, may be introduced to a portion of the amorphous substrate and melt the portion. If the condition of the molten region is adequate to induce nucleation (e.g. supercooling), crystals may nucleate as described by the classical nucleation theory. The crystals may nucleate via two schemes. The crystals may nucleate heterogeneously on pre-existing seeds. The pre-existing seeds may be grain boundaries of pre-existing crystals that did not melt upon introduction of the energy. The pre-exiting seeds may also be the boundary between the molten region and adjacent solid region. If the pre-existing seeds are absent, the crystals may nucleate homogeneously. Upon nucleation, the crystals may grow until the growth is halted.

In the solid phase transformation mechanism 10b, the phase transformation may occur despite the absence of the melting. For example, crystals may nucleate in the region introduced with energy, and the nucleation may be followed by the growth of the nucleated crystals. As in the case of the melt process, nucleation during SPC can occur heterogeneously if pre-existing seeds exist, or homogeneously if such seeds are absent.

In the present disclosure, particles may be introduced to a substrate to induce the phase transformation. The phase transformation may be that from the amorphous phase to one of the polycrystalline and/or mono-crystalline phases. In addition, the phase transformation may occur via nucleation and growth of the crystals. To induce the transformation, the particles may be introduced near the upper surface of the substrate, the lower surface of the substrate, or a region between the upper and lower surfaces, or a combination thereof. If the substrate comprises two or more different materials, the particles may be introduced to a region near the interface of the different materials.

Numerous types of particles may be introduced to induce the phase transformation. For example, the particles that are chemically and/or electrically inert with respect to the substrate may be used. However, chemically and/or electrically active material may also be used. As noted above, the particles may be charged or neutral sub-atomic particles, atomic particles, or molecular particles, or a combination thereof. In some embodiments, molecular particles are preferred. In other embodiments, cluster particles are preferred. Molecular and cluster particles may be preferred as they may be introduced to the substrate at much higher dose and energy. In particular, molecular and cluster particles introduced to a substrate may disintegrate on impact, and the kinetic energy of the particles may be shared in the ratio of the atomic masses of the particle atoms. The overlapping collision cascades may achieve result similar to introduction of atomic particles at much higher dose rate. Due to their greater mass, the molecular particles may also be introduced to the substrate at much higher energy. The generation of atomic and molecular species in implanters, PLAD and PIII will be familiar to those skilled in the art. A detailed description of the generation of cluster particles may be found in U.S. Pat. No. 5,459,326, which is incorporated in entirety by reference.

The choice of the particles introduced to the substrate may also depend on the effect of the particles on the substrate. Some characteristics and illustrative examples are shown in Table 1.

TABLE 1

| Characteristic | Example Species |
|---|---|
| Electrically | Ge, Si, C, F, N H, He, Sn, Pb, |
| inactive in silicon | hydrocarbon molecules, molecules |
| | containing C and two or more other |
| | elements, hydrides of silicon such as |
| | tetra-silane, molecules containing Si and |
| | two or more other elements |
| Dopants | B, P, As, Sb, In, Ga, Sb, Bi, |
| Shallow Junction Co- | C, F |
| implant species | |
| Amorphizing | Noble Gases (including He, Xe), Ge, Si |
| Strain producing | Ge, C |
| Bandgap engineering | Yb, Ti, Hf, Zr, Pd, Pt, Al |
| Passivating | H, D |
| Defect Pinning | N |
| Crystallization | Ni, metals |
| catalysts | |

When the particles are introduced to the substrate, the kinetic energy of the particles may be transferred to the substrate. The magnitude of the transferred kinetic energy may depend on the size, mass, and energy of the particles. For example, heavy ions introduced to a substrate may experience more nuclear stopping than lighter ions. When the particles lose their kinetic energy via the nuclear stopping mechanism, the mechanism tends to form defects such as, for example, dangling bonds, vacancies, and di-vacancies, whose presence may enhance the crystallization process. At the same time, kinetic energy transferred to the substrate via electronic stopping may cause crystallization.

Depending on the energy of the particles, the location of the particles delivery, and the properties of the substrate (e.g. thermal conductivity, heat capacity and melting temperature of the substrate), nucleation of crystals may be initiated at the upper surface of the substrate; the lower surface of the substrate; the region between the upper and lower surfaces; or near the interface of different materials. Thereafter, the phase transformation may continue in a direction away from the location where the transformation is initiated.

Unlike the radiation based phase transformation, energy deposited to the substrate via the particle introduction may peak at the surface or, alternatively, below the surface. In addition, the particles may be introduced to the substrate at a constant energy. Alternatively, the particles may be introduced at varied energies. For example, the energy of the particles introduced to the substrate may change while the particles are being introduced. The change in the energy may occur continuously or in a sequence. If a beam-line particle system is used, the particle energy may be changed during the particle introduction using acceleration or deceleration voltage associated with beam-line systems described herein. If PLAD, PIII, or other plasma based system is used, the energy may be changed during the introduction by varying the voltage applied to the substrate.

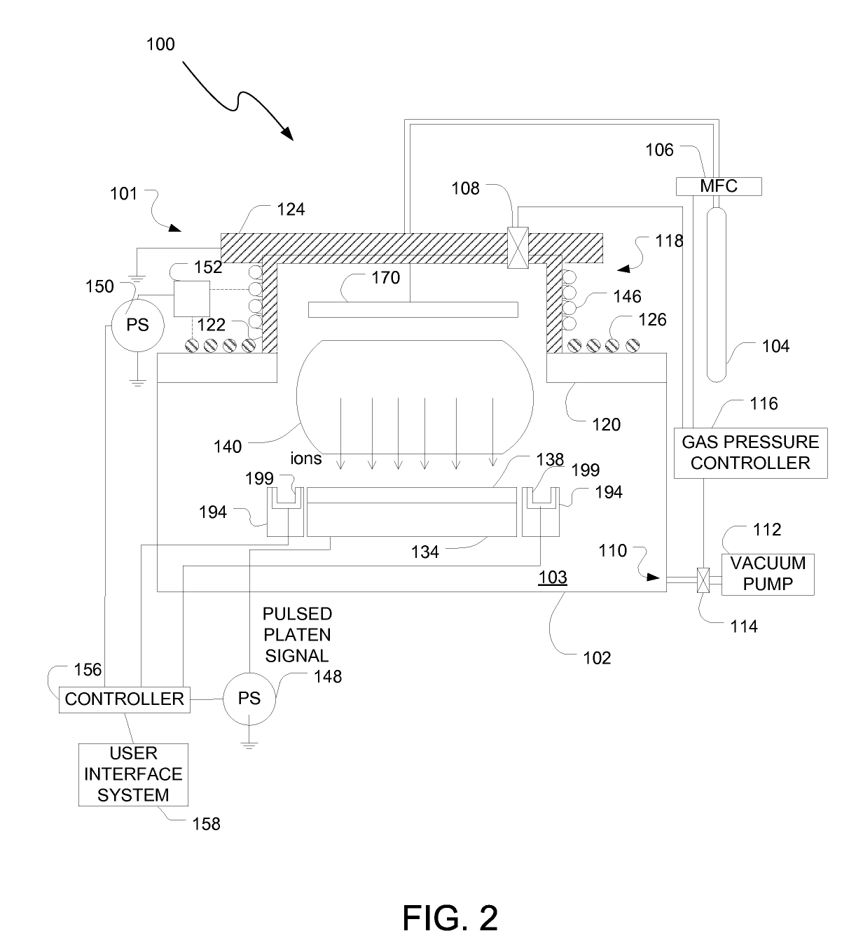

FIG. 2 shows a representative illustration of a plasma assisted doping system (PLAD). The plasma doping system 100 includes a process chamber 102 defining an enclosed volume 103. A platen 134 may be positioned in the process chamber 102 to support a substrate 138. In one instance, the substrate 138 may be a semiconductor wafer having a disk shape, such as, in one embodiment, a 300 millimeter (mm) diameter silicon wafer. In other embodiments, the substrate may be metal foil or any of the materials noted above. The substrate 138 may be clamped to a flat surface of the platen 134 by electrostatic or mechanical forces. In one embodiment, the platen 134 may include conductive pins (not shown) for making connection to the substrate 138.

A gas source 104 provides a dopant gas to the interior volume 103 of the process chamber 102 through the mass flow controller 106. A gas baffle 170 is positioned in the process chamber 102 to deflect the flow of gas from the gas source 104. A pressure gauge 108 measures the pressure inside the process chamber 102. A vacuum pump 112 evacuates exhausts from the process chamber 102 through an exhaust port 110 in the process chamber 102. An exhaust valve 114 controls the exhaust conductance through the exhaust port 110.

The plasma doping system 100 may further include a gas pressure controller 116 that is electrically connected to the mass flow controller 106, the pressure gauge 108, and the exhaust valve 114. The gas pressure controller 116 may be configured to maintain a desired pressure in the process chamber 102 by controlling either the exhaust conductance with the exhaust valve 114 or a process gas flow rate with the mass flow controller 106 in a feedback loop that is responsive to the pressure gauge 108.

The process chamber 102 may have a chamber top 118 that includes a first section 120 formed of a dielectric material that extends in a generally horizontal direction. The chamber top 118 also includes a second section 122 formed of a dielectric material that extends a height from the first section 120 in a generally vertical direction. The chamber top 118 further includes a lid 124 formed of an electrically and thermally conductive material that extends across the second section 122 in a horizontal direction.

The plasma doping system may further include a source 101 configured to generate a plasma 140 within the process chamber 102. The source 101 may include a RF source 150, such as a power supply, to supply RF power to either one or both of the planar antenna 126 and the helical antenna 146 to generate the plasma 140. The RF source 150 may be coupled to the antennas 126, 146 by an impedance matching network 152 that matches the output impedance of the RF source 150 to the impedance of the RF antennas 126, 146 in order to maximize the power transferred from the RF source 150 to the RF antennas 126, 146.

The plasma doping system 100 also may include a bias power supply 148 electrically coupled to the platen 134. The bias power supply 148 is configured to provide a pulsed platen signal having pulse on and off time periods to bias the platen 134, and, hence, the substrate 138, and to accelerate ions from the plasma 140 toward the substrate 138 during the pulse on time periods and not during the pulse off periods. The bias power supply 148 may be a DC or an RF power supply.

The plasma doping system 100 may further include a shield ring 194 disposed around the platen 134. As is known in the art, the shield ring 194 may be biased to improve the uniformity of implanted ion distribution near the edge of the substrate 138. One or more Faraday sensors such as an annular Faraday sensor 199 may be positioned in the shield ring 194 to sense ion beam current.

The plasma doping system 100 may further include a controller 156 and a user interface system 158. The controller 156 can be or include a general-purpose computer or network of general-purpose computers that may be programmed to perform desired input/output functions. The controller 156 can also include other electronic circuitry or components, such as application-specific integrated circuits, other hardwired or programmable electronic devices, discrete element circuits, etc. The controller 156 also may include communication devices, data storage devices, and software. For clarity of illustration, the controller 156 is illustrated as providing only an output signal to the power supplies 148, 150, and receiving input signals from the Faraday sensor 199. Those skilled in the art will recognize that the controller 156 may provide output signals to other components of the plasma doping system and receive input signals from the same. The user interface system 158 may include devices such as touch screens, keyboards, user pointing devices, displays, printers, etc. to allow a user to input commands and/or data and/or to monitor the plasma doping system via the controller 156.

In operation, the gas source 104 supplies a primary dopant gas containing a desired dopant for implantation into the substrate 138. The gas pressure controller 116 regulates the rate at which the primary dopant gas is supplied to the process chamber 102. The source 101 is configured to generate the plasma 140 within the process chamber 102. The source 101 may be controlled by the controller 156. To generate the plasma 140, the RF source 150 resonates RF currents in at least one of the RF antennas 126, 146 to produce an oscillating magnetic field. The oscillating magnetic field induces RF currents into the process chamber 102. The RF currents in the process chamber 102 excite and ionize the primary dopant gas to generate the plasma 140.

The bias power supply 148 provides a pulsed platen signal to bias the platen 134 and, hence, the substrate 138 to accelerate ions from the plasma 140 toward the substrate 138 during the pulse on periods of the pulsed platen signal. The frequency of the pulsed platen signal and/or the duty cycle of the pulses may be selected to provide a desired dose rate. The amplitude of the pulsed platen signal may be selected to provide a desired energy. With all other parameters being equal, a greater energy will result in a greater implanted depth. The plasma doping system 100 may incorporate hot or cold implantation of ions in some embodiments.

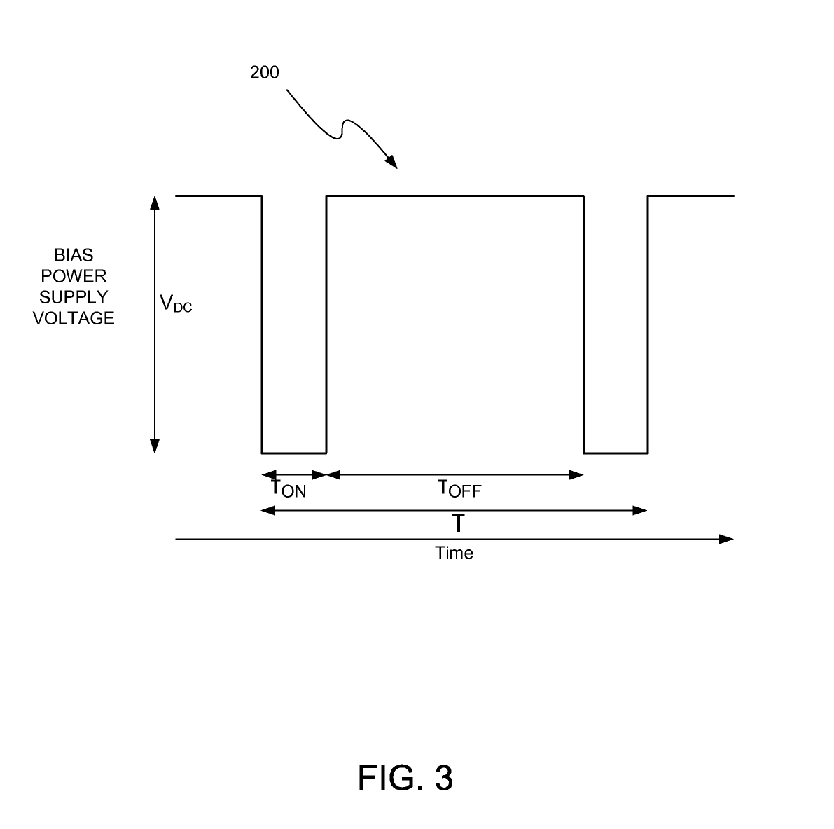

FIG. 3 shows a waveform of the voltage supplied by the bias power supply 148 to bias the platen 134. Typically, the bias voltage is pulsed from ground to a negative voltage to attract positive ions from the plasma 140. In this embodiment, the voltage waveform 200 is a square wave, having a period of T, where the voltage is applied during a first portion of the period, namely TON and is not applied during a second portion of the period, namely τ_{OFF}.

In one embodiment, the plasma 140 is formed using a deposition-related species, and an energy-carrying species. The deposition-related species contains the material that is to be crystallized. In one embodiment, a gas containing silicon, such as silane (SiH₄), is used as the deposition-related species. Other deposition-related species may also be employed, such as semiconductor materials like SiGe, Ge, Si:C, Si:Sn. Alternatively, insulating materials, such as SiN, SiO₂, AlN, AlO₂ and BN can also be deposited. Alternatively, conductive materials including metals, silicides and germanides can also be deposited. The energy-carrying species is a second species, which is used to impart energy to the previously deposited material. Species, such as those shown in Table 1, can be used for this function. In certain embodiments, inert gasses, such as Argon and Xenon are preferred.

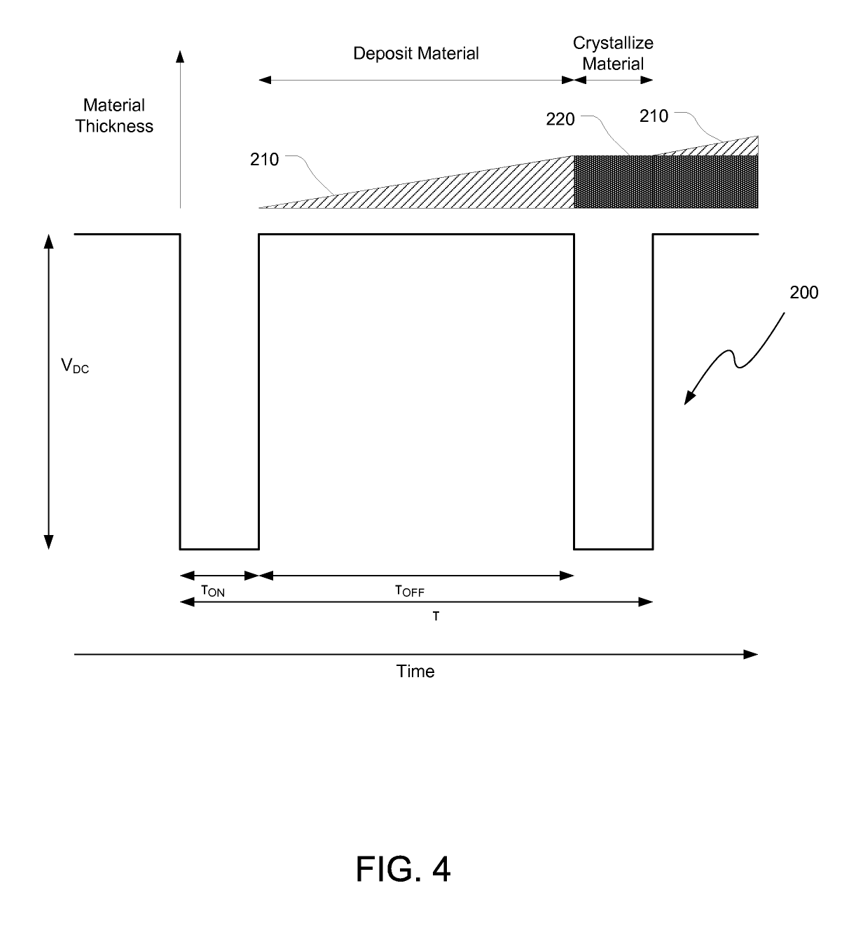

During the period when the bias voltage is not applied to the platen (τ_{OFF}), the deposition-related species, such as silane, may be deposited on the substrate, such as by plasma deposition. The τ_{OFF} duration is determined so as to be sufficiently long to allow an adequate thickness of material, such as silicon, to be deposited on the substrate. However, the duration must not be so long as to deposit more silicon than can be crystallized. FIG. 4 shows the voltage waveform of FIG. 3, in addition to the state of the material substrate. Thus, as time elapses, the thickness of the material 210 on the substrate grows. The thickness of the deposited material is a function of the flux of the deposition-forming species to the surface. These species can be molecules or electrically-neutral radicals or ions. The flux of neutrals is a function of the chamber pressure, and the flux of ionized species is a function of the plasma density and temperature. The deposition rate also depends on the sticking coefficient of each of these species, which is a function of the gas-phase species, the substrate material, and the temperature. The deposition rate can also be influenced by ionization-induced reactions on the substrate including, e.g. ion-induced polymerization. The actual deposition rate is usually determined empirically and is within the ordinary skill in the art. When an appropriate thickness is reached, as defined above, the bias voltage is applied. This voltage attracts ionized particles toward the substrate. The thickness to be grown during the τ_{OFF} duration may be less than or equal to that which can be recrystallized during the τ_{ON} duration.

The voltage V_{DC} determines the distance that the particles will penetrate the film. Greater voltages cause the particles to penetrate deeper into the film. Those skilled in the art will appreciate that modeling programs are available to correlate the energy of the incident ions and the range (i.e. depth of ion penetration). In some embodiments, V_{DC} may be chosen such that the projected range of the particles reaches somewhere between halfway through the deposited film, and just beyond the thickness of the film, such as approximately 1.5 times the film thickness. The ideal range may be determined empirically for each particular application. The range is also dependent on the mass of the energy-carrying ion. Heavier species require more energy to reach the desired range. One advantage of using heavier species is that each ion deposits more energy into the film. This energy is required for crystallization.

Those of skill in the art realize that there is a certain energy, known as the free energy of recrystallization (ΔG), needed to transition amorphous silicon to its crystalline state. The free energy of recrystallization (ΔG) is typically expressed in joules/mole. Thus, using this value, and knowing the thickness and density of the deposited film, the areal energy density, ΔE, required to crystallize the deposited film can be calculated as:

ΔE=ΔG×Δthickness×density,

where density is in mols/cm³. Using the required energy needed (ΔE), and the desired ion range (which determines V_{DC}), the required dose of ions can be determined using the formula:

Dose=ΔE/V_{DC}.

The pulse width, τ_{ON}, can then be calculated to delivered a sufficient dose to the film to cause recrystallization, based on the DC current of the plasma, j. In this case, the pulse width can be defined as:

τ_{ON}=Dose/j=ΔE/(j×V_{DC}).

For example, if it requires 4 mJ/cm² to recrystallize a film layer 20 Å thick, one may choose 200 eV Ar ions, for which their expected range, Rₚ, is about 15 Å. If the plasma current is 0.1 A/cm², then:

$${τ}_{on} = \frac{4 \times {10}^{- 3} J}{{cm}^{2}} \frac{{cm}^{2}}{0.1 A} \frac{1}{200 V} 0.2 m sec$$

Alternatively, one may define a metric for a PLAD system, such as dose-per-pulse (DPP), which is the amount of dose (ions/cm²) delivered during each TON pulse. To reduce implant time, the plasma density may be increased by increasing the plasma source power. This increases the number of ions in the plasma, and therefore increases the dose per pulse. The effect of this increased source power on the deposition properties and rate may be affected.

The pulse is used to transform the amorphous material into a crystalline structure 220. Following the termination of the pulse, material 210 begins building up on top of the recently crystallized material 220 for a duration of τ_{OFF}. The pulse is then asserted, thereby crystallizing the newly deposited material. This process is repeated until the desired thickness is reached. In some embodiments, this process is repeated multiple times.

For example, assume that the total cycle time is 2 milliseconds, with a τ_{ON} duration of 0.3 milliseconds. Also assume that film is deposited at a rate of 2 angstroms per cycle. Thus, the effective film thickness growth is approximately 0.1 micrometer per second. Thus, to deposit a layer of 100 angstroms, 50 cycles, totaling 100 milliseconds, is required.

As described above, crystallization is the result of energy impacted by ions striking the film. The energy-carrying species used to impart this energy may vary, depending on application, as described above. In some embodiments, an inert gas, such as argon, xenon, neon or helium is used to provide these energy-carrying species. The choice of a particular gas may impact several aspects of the process and these must be considered simultaneously to develop the overall process. For example, heavier inert atoms, such as xenon, have lower ionization potential, therefore a relatively low inert concentration in the plasma may be needed to create the desired ratio of deposition-related ions (i.e. silicon) to energy-carrying ions. Conversely, to achieve the desired ratio of energy-carrying ions to deposition-related ions in the plasma with a gas that is difficult to ionize (such as helium), it may be necessary to introduce a higher concentration of the inert gas into the chamber. A change in the type or concentration of the energy-carrying species may have an effect on the deposition time. In another embodiment, elements such as silicon, carbon or germanium may be used as the energy-carrying species.

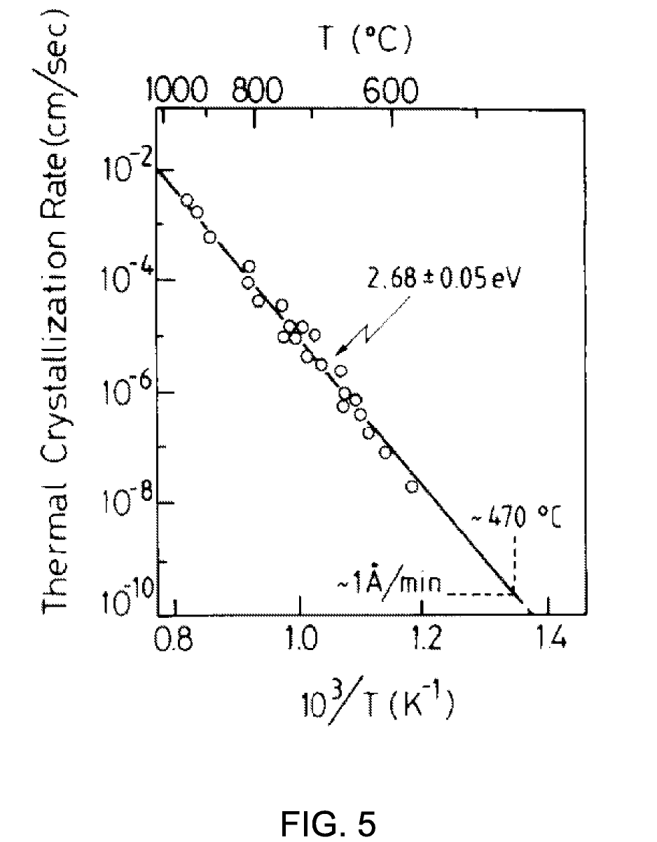

In another embodiment, the substrate is maintained at an elevated temperature. This elevated temperature reduces the energy deposition requirement. FIG. 5 shows the epitaxial growth rate as a function of temperature. Note that the growth rate increases at higher temperatures. However, the current process is effective at low temperatures, thereby enabling the use of substrates that may deform at higher temperatures, such as glass.

The lower the substrate temperature, the more advantage offered by energy-deposition processes. To maximize the process speed, it is likely desirable to hold the substrate at the maximum temperature commensurate with the other process constraints. For example, if the substrate melts, deforms, or has a high coefficient of thermal expansion, then the substrate temperature will probably be best to be as low as possible. With the substrate temperature determined by these other constraints, the conditions (pressure, power, flow, etc.) for the deposition/energy-deposition process can then be determined.

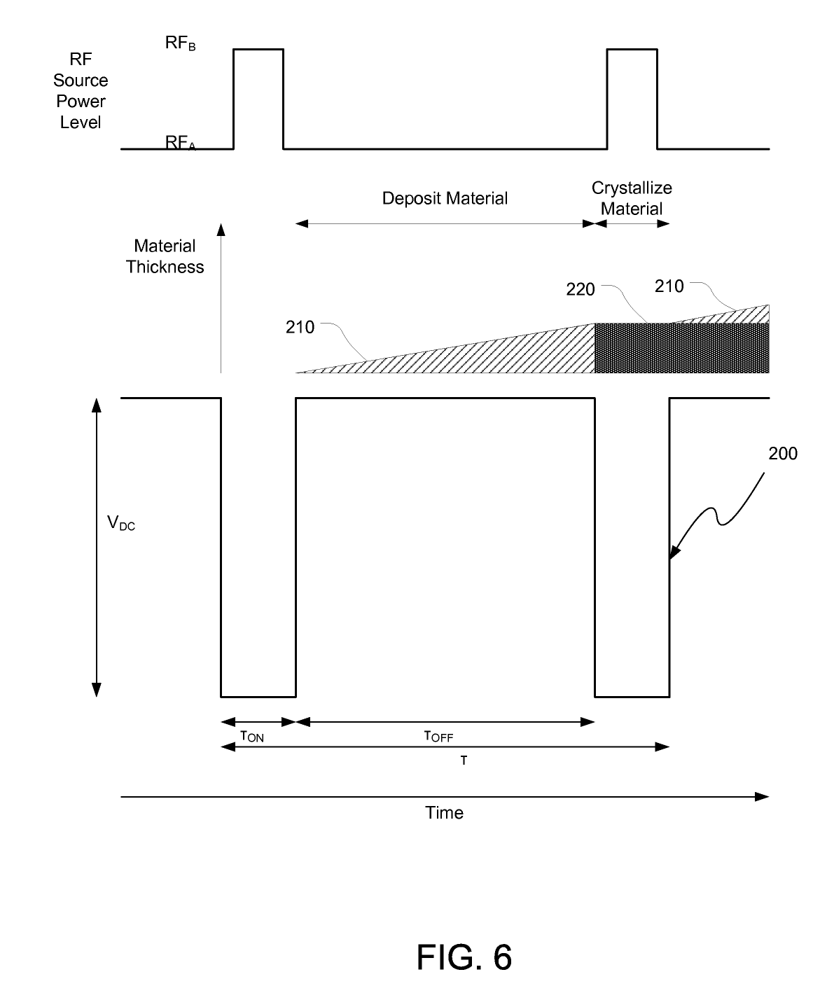

In other embodiments, it may be advantageous to modulate the RF source power 150 to improve the ability to crystallize the deposited material 210. Recall that the RF source power 150 drives the antennas which produce the plasma (see FIG. 2). FIG. 6 shows a timing diagram showing the bias voltage of the substrate and the magnitude of the source power 150. In this embodiment, the RF source power is increased during the period where the energy-carrying ions are attracted to the substrate (TON). This increase in power results in a corresponding increase in plasma density and the number of ions available to be implanted in the material. This increased number of available ions may reduce the time duration required for the bias voltage pulse to recrystallize the material. In another embodiment, it may be advantageous to lower the RF source power during the recrystallization pulse.

FIG. 6 shows two different voltage levels for the RF source power. However, the disclosure is not limited to this embodiment. For example, it may be beneficial to vary the peak voltage of the recrystallization pulse throughout the deposition process. In one embodiment, a greater voltage is used at the start of the process to aid in crystallization. The RF source power is then decreased so as not to amorphize previously crystallized layers of the material. In a second embodiment, the voltage is increased as the process continues, thereby delivering more energy to previously deposited layers.

The energy delivered can also be varied to affect the crystalline structure produced. More energy may result in a very crystallized structure, while a lower dose may result in a reduced amount of crystallization.

Thus, a number of different parameters may be altered to create the desired operating condition. For example, pressure, bias voltage, pulse width duration, RF source power, flow and gas composition can be varied to create a desired operating condition. In some embodiments, only one parameter is varied between two operating conditions, e.g. the bias voltage or the pulse width duration. In other embodiments, two of more parameters are varied simultaneously between two operating conditions. For example, RF source power and bias voltage may both be varied to create two different operating conditions.

The ability to control the amount of crystallization of a material may be advantageous in the development of solar cells. Traditional solar cells may include an n-doped layer, a p-doped layer and an intervening p-n junction. Photons of a specific energy strike the atoms within the solar cell and create an electron-hole pair. However, traditional solar cells are limited in that only photons possessing a specific energy are useful. Those photons with an energy below the band-gap energy of the cell material cannot be used. Those photons with an energy above the band-gap energy of the cell material generate an electron-hole pair. However, the additional energy is lost, typically as heat.

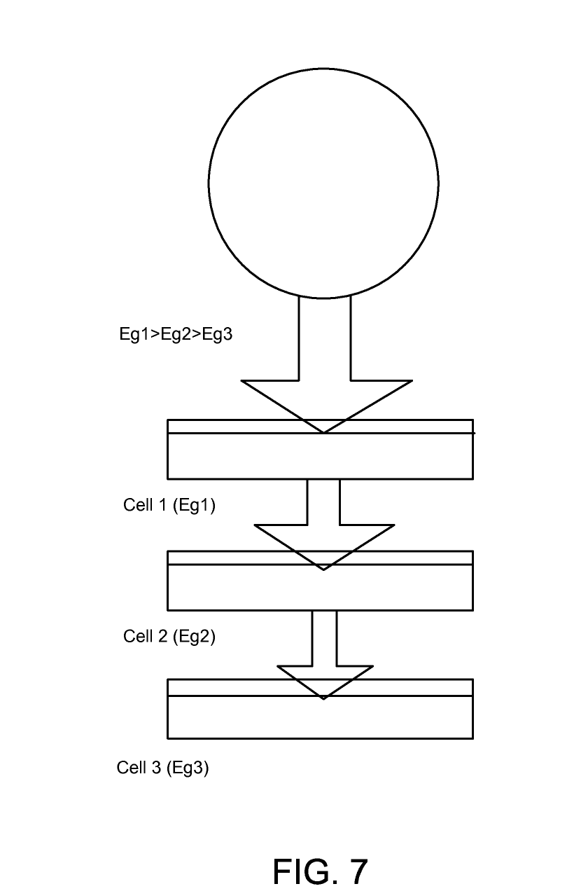

To capture more energy from the solar spectrum, it is beneficial to utilize cells having materials of different band-gap energy. For example, a first p-n junction using a material having a first band-gap energy can receive the solar energy. Photons with an energy greater than or equal to the band-gap energy of this material generate electron-hole pairs. Photons with an energy less than the band-gap energy of the first p-n junction pass through to a second p-n junction using a material having a second band-pass energy less than that of the first p-n junction. Photons with an energy greater than or equal to the band-gap energy of this second material generate electron-hole pairs. Photons with an energy less than the band-gap energy of the second material pass through to a third p-n junction. This configuration is also known as a tandem cell. A pictorial representation of this structure is shown in FIG. 7. In this figure, cell 1 has a higher band-gap energy than cell 2, which has a higher band-gap energy than cell 3. This structure can continue indefinitely. Using this arrangement, photons will continue to pass through the cells until they encounter a material having a band-gap energy less than or equal to their energy. In this way, the efficiency of converting solar energy into electrical energy is maximized.

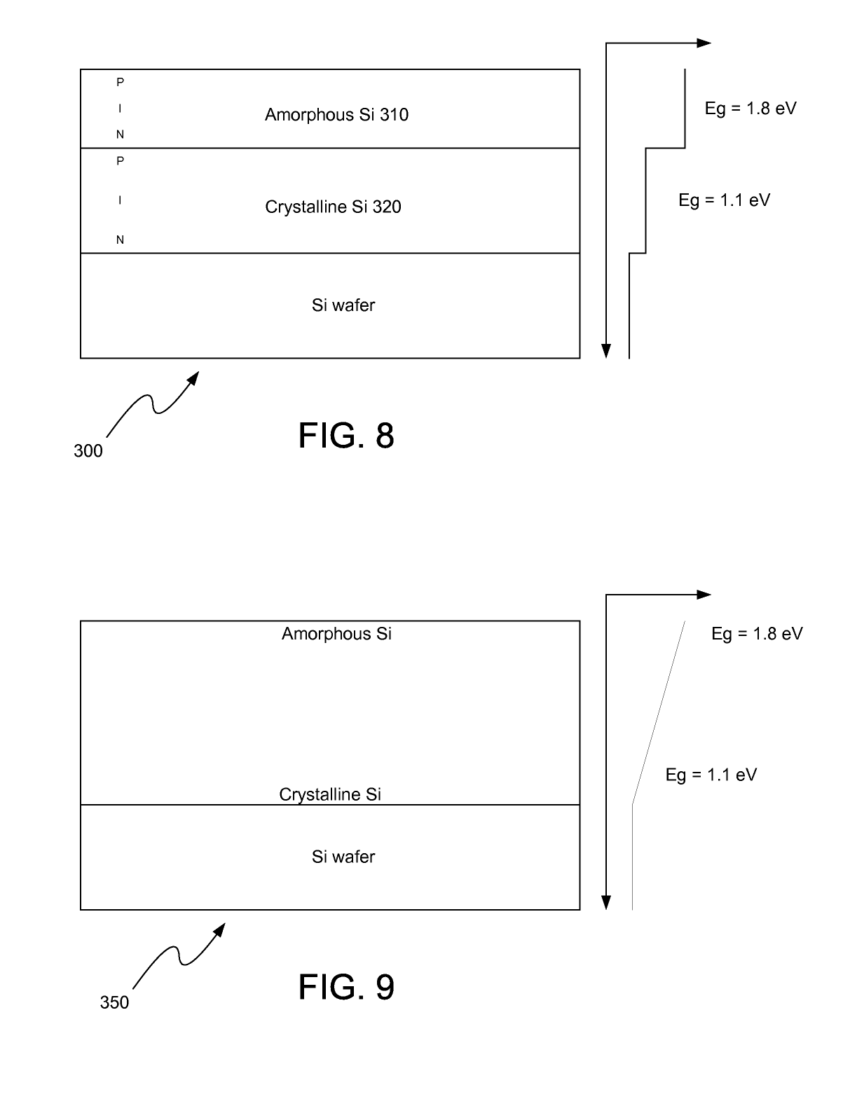

The disclosed process may aid in the creation of materials with varying band-gap energies. FIG. 8 shows a schematic diagram of a tandem cell 300, wherein the upper cell (310 that which receives the solar energy first) is made from amorphous silicon, which has a bandgap energy of 1.8 eV. The upper cell 310 is doped so as to have a p-doped region and an n-doped region, with an intrinsic layer between them. The second cell 320 is created with crystalline silicon (either microcrystalline or polycrystalline), which has a lower bandgap energy of 1.1 eV. The second cell 320 is doped in a similar fashion so as to create a p-i-n structure, as shown in FIG. 8. Typically, a very thin highly doped layer is between the n-doped region of the upper cell 310 and the p-doped region of the second cell 320 to provide electrical contact between the two p-i-n structures. Photons having an energy of 1.8 eV or greater generate electron hole pairs in the amorphous silicon 310. Those photons with an energy level below this value will pass through the amorphous silicon and into the crystalline silicon 320. Those photons with an energy level of 1.1 eV or greater will generate an electron-hole pair in the crystalline structure 320.

To create a substrate having these characteristics, the disclosed process may be utilized. Early depositions of silicon layers are made with the bias voltage pulsed as described in connection with FIG. 4. The pulsing of the bias voltage transforms the deposited silicon from its amorphous state to a crystalline state. Once a sufficiently thick crystalline layer has been deposited, subsequent depositions are made using a reduced bias voltage, a reduced pulse duration or both. In some embodiments, the crystalline layer is made thick enough to absorb most of the photons near the c-Si bandgap. This thickness is a function of the absorptivity of Si at this wavelength. Practically, it may be a micron or more. In some embodiments, the bias voltage is not applied, and amorphous silicon is continuously deposited until the desired thickness has been achieved.

This process produces a film having discrete layers with specific bandgap energies. This method allows photons having energy levels greater than 1.1 eV to be used to create electrical energy. However, photons with energies between 1.1 eV and 1.8 eV will necessarily be inefficient as the excess energy (that energy above 1.1 eV) will be transformed into heat. A second embodiment creates a substrate with a continuously changing crystalline structure, as opposed to two or more discrete layers. FIG. 9 shows a substrate 350 where the amount of crystallization decreases moving from the bottom to the top of the substrate. As the amount of crystallization decreases, the bandgap energy of the material increases.

The substrate 350 of FIG. 9 can be achieved using the disclosed method. The first layers are deposited and crystallized as described above. As subsequent layers are deposited, the bias voltage, pulse duration or both are gradually reduced. The reduction in bias voltage or pulse duration reduces the amount of crystallization in the most recently deposited layer, thereby increasing its bandgap energy. This process continues until the substrate is completed. In some embodiments, as shown in FIG, 9, the top of the substrate is amorphous silicon, while the inner layers are crystalline silicone, having a much lower bandgap energy.

Many solar cell devices have a p-i-n structure with relatively thin doped regions (p and n) surrounding a relatively thick “i” (intrinsic) region. The “i” region is where absorption occurs (i.e. where the photon is absorbed to create electron and hole pair). To grow the film for a solar cell, the first dopant (e.g. n-type) would be supplied to the chamber during the silicon deposition, thereby creating an n-type layer. When a sufficiently thick n-type layer was produced, the n-type dopant would be disabled, while the silicon deposition continued. Since there are no dopants present, an undoped intrinsic (“i”) region is then grown. Afterwards, a second dopant (e.g. p-type) is supplied to the chamber during the silicon deposition, thereby producing the p-type layer. Each of these layers can be arbitrarily thick, as this is simply a function of time. Similarly, the order that these layers are produced can vary, or be repeated if required. The dopants typically used are well known in the art and include but are not limited to B, P, As, Sb, In, and Ga.

What is claimed is:

1. A method of growing material on a substrate comprising:
providing a plasma chamber, wherein said plasma chamber comprises an antenna adapted to create a plasma from supplied gasses;
placing said substrate in said plasma chamber on a platen which can be biased to a plurality of voltages;
supplying a first species to said plasma chamber;
supplying a second species to said plasma chamber;
performing a plasma deposition phase, wherein material from said first species is deposited onto said substrate while at a first operating condition; and
performing an ion implantation phase while at a second operating condition, wherein ions of said second species are implanted into said material deposited during said plasma deposition phase.

2. The method of claim 1, where said first operating condition and said second operating condition each comprise a bias voltage for said platen, a pulse duration of said bias voltage, a power for said antenna, a pressure within said chamber, a flow rate of said first species, or a flow rate of said second species.

3. The method of claim 1, wherein said first species comprises a deposition related gas.

4. The method of claim 3, wherein said first species comprises silicon.

5. The method of claim 1, wherein said second species comprises an energy-carrying gas.

6. The method of claim 5, wherein said second species comprises an inert gas.

7. The method of claim 1, wherein said first operating condition comprises a ground voltage applied to said platen.

8. The method of claim 1, wherein said second operating condition comprises a second voltage applied to said platen which is more negative than a first voltage applied to said platen during said first operating condition.

9. The method of claim 1, wherein a square wave voltage is applied to said platen.

10. The method of claim 1, wherein said plasma deposition phase and said ion implanting phase are repeated a plurality of times.

11. A method of fabricating a material with multiple band gap energies, comprising:
providing a plasma chamber, wherein said plasma chamber comprises an antenna adapted to create a plasma from supplied gasses;
placing said substrate in said plasma chamber on a platen which can be biased to a plurality of voltages;
supplying a first species to said plasma chamber;
supplying a second species to said plasma chamber;
performing a first plasma deposition phase, wherein material from said first species is deposited onto said substrate while at a first operating condition;
performing a first ion implantation phase while at a second operating condition, wherein ions of said second species are implanted into said material deposited during said first plasma deposition phase so as to crystallize said material to a first crystallization level;
repeating said first plasma deposition phase and said first ion implantation phase a plurality of times so as to create a layer of said material at said first crystallization level;
performing a second plasma deposition phase, wherein material from said first species is deposited onto said substrate while at a third operating condition;
performing a second ion implantation phase while at a fourth operating condition, wherein ions of said second species are implanted into said material deposited during said second plasma deposition phase so as to crystallize said material to a second crystallization level, wherein said material at said first crystallization level has a different band gap energy than said material at said second crystallization level; and
repeating said second plasma deposition phase and said second ion implantation phase a plurality of times so as to create a layer of said material at said second crystallization level.

12. The method of claim 11, where said first operating condition, said second operating condition, said third operating condition and said fourth operating condition each comprise a bias voltage for said platen, a pulse duration of said bias voltage, a power for said antenna, a pressure within said chamber, a flow rate of said first species, or a flow rate of said second species.

13. The method of claim 11, further comprising
performing a third plasma deposition phase, wherein material from said first species is deposited onto said substrate while at a fifth operating condition;
performing a third ion implantation phase while at a sixth operating condition, wherein ions of said second species are implanted into said material deposited during said third plasma deposition phase so as to crystallize said deposited material to a third crystallization level, wherein said material at said first crystallization level and said second crystallization level have a different band gap energy than said material at said third crystallization level; and
repeating said third plasma deposition phase and said third ion implantation phase a plurality of times so as to create a layer of material at said third crystallization level.

14. The method of claim 11, wherein said material comprises a plurality of levels of crystallization, wherein each of said levels of crystallization comprises an associated band gap energy.

15. A method of fabricating a solar cell on a substrate comprising:
providing a plasma chamber, wherein said plasma chamber comprises an antenna adapted to create a plasma from supplied gasses;
placing said substrate in said plasma chamber on a platen which can be biased to a plurality of voltages;
supplying a first species, a second species and first dopant to said plasma chamber;
performing a first growing step, wherein said first dopant and said second species are implanted, so as to create a first doped layer;
disabling said first dopant to said plasma chamber;
performing a second growing step, so as to create an intrinsic layer having a first bandgap energy;
supplying a second dopant to said plasma chamber; and
performing a third growing step, wherein said second dopant and said second species are implanted, so as to create a second doped layer,
wherein each of said growing steps comprises
performing a plasma deposition phase, wherein material from said first species is deposited onto a substrate while at a first operating condition, performing an ion implantation phase at a different operating condition, wherein ions of at least said second species are implanted into said material deposited during said plasma deposition phase, and sequentially repeating said plasma deposition phase and said ion implantation phase a plurality of times.

16. The method of claim 15, where said first operating condition and said different operating condition each comprise a bias voltage for said platen, a pulse duration of said bias voltage, a power for said antenna, a pressure within said chamber, a flow rate of said first species, or a flow rate of said second species.

17. The method of claim 15, further comprising:
supplying a third dopant to said plasma chamber;
performing a fourth growing step, wherein said third dopant and said second species are implanted, so as to create a third doped layer;
disabling said third dopant to said plasma chamber performing a fifth growing step, having a different operating condition during its respective ion implantation phase than said second growing step, so as to create an intrinsic layer having a second bandgap energy;
supplying a fourth dopant to said plasma chamber; and
performing a sixth growing step, wherein said fourth dopant and said second species are implanted, so as to create a fourth doped layer.

18. The method of claim 15, further comprising:
prior to supplying said second dopant, performing a fourth growing step, having a different operating condition during its respective ion implantation phase than said second growing step, so as to create an intrinsic layer having a second bandgap energy different than first first bandgap energy;

19. The method of claim 18, further comprising:
performing a fifth growing step having a different operating condition during its respective ion implantation phase than said second and said fourth growing steps, after said fourth growing step, so as to create an intrinsic layer having a third bandgap energy different than said first and second bandgap energies.

20. The method of claim 15, further comprising:
prior to supplying said second dopant, performing a plurality of growing steps, each growing step having a different operating condition during its respective ion implantation phase, so as to create an intrinsic layer having a plurality of bandgap energies.
